(19) United States
(12) Patent Application Publication
(10) Pub. No.: US 2009/0166691 A1
(43) Pub. Date: Jul. 2, 2009

(54) Image Sensor and Method of Manufacturing the Same

(76) Inventor: Jong Min Kim, Guro-gu (KR)

Correspondence Address: SALIWANCHIK LLOYD & SALIWANCHIK;A PROFESSIONAL ASSOCIATION, PO Box 142950, GAINESVILLE, FL, 32614, US

(21) Appl. No.: 12/262,201

(22) Filed: Oct. 31, 2008

(30) Foreign Application Priority Data
Dec. 27, 2007 (KR) 10-2007-0139211

(51) Int. Cl. H01L 31/00; H01L 21/00

(52) U.S. Cl. 257/292; 438/69; 257/E31.001; 257/E21.001

(57) ABSTRACT

Image sensors and manufacturing methods thereof are provided. An image sensor according to an embodiment comprises a second conductive type diffusion layer formed on a first conductive type substrate; a device isolating layer formed in the second conductive type diffusion layer to isolate the second conductive type diffusion layer according to unit pixel; a gate formed on the second conductive type diffusion layer; a first conductive type area formed on a surface of the second conductive type diffusion layer at one side of the gate; a first conductive type well area formed in the second conductive type diffusion layer at the other side of the gate; and a floating diffusion area formed in the first conductive type well area.

### CROSS-REFERENCE TO RELATED APPLICATION

The present application claims the benefit under 35 U.S.C. §119 of Korean Patent Application No. 10-2007-0139211, filed Dec. 27, 2007, which is hereby incorporated by reference in its entirety.

### BACKGROUND

An image sensor, which is a semiconductor device for converting an optical image into an electrical signal, is generally classified as a charge coupled device (CCD) image sensor or a complementary metal oxide semiconductor (CMOS) image sensor (CIS).

The CMOS image sensor is a device adopting a switching scheme using a control circuit and a signal processing circuit as a peripheral circuit and sequentially detecting an output for each unit pixel using the same.

The CMOS image sensor includes a MOS transistor and a photodiode that receives light to generate photo charges arranged according to unit pixel.

As the CMOS image sensor becomes highly integrated, the size of the unit pixel is reduced accordingly and the photodiode being a photo response region is also reduced.

The reduction of the photodiode area reduces the dynamic range when the image sensor is operated, leading to a deterioration of saturation and lag characteristics.

Therefore, a need exists for an improvement of charge transfer efficiency by changing a structure of a photodiode in an image sensor.

### BRIEF SUMMARY

Embodiments of the present invention provide an image sensor and a method of manufacturing the same capable of improving photo sensitivity by an extension of a photodiode area in a unit pixel.

An image sensor according to an embodiment can include: a second conductive type diffusion layer formed on a first conductive type substrate; a device isolating layer formed in the second conductive type diffusion layer to isolate the second conductive type diffusion layer for each unit pixel; a gate formed on the second conductive type diffusion layer; a first conductive type area formed on a surface of the second conductive type diffusion layer to be aligned at one side of the gate; a first conductive type well area formed in the second conductive type diffusion layer at the other side of the gate; and a floating diffusion area formed in the first conductive type well area. By arranging the second conductive type diffusion layer over a larger area of the unit pixel, the photodiode area is extended.

A method of manufacturing an image sensor according to an embodiment can comprise: forming a second conductive type diffusion layer on a first conductive type substrate; forming a device isolating layer in the second conductive type diffusion layer to isolate the second conductive type diffusion layer for each unit pixel; forming a gate on the second conductive type diffusion layer; forming a first conductive type area on a surface of the second conductive type diffusion layer at one side of the gate; forming a first conductive type well area in the second conductive type diffusion layer at the other side of the gate; and forming a floating diffusion area in the first conductive type well area.

### BRIEF DESCRIPTION OF THE DRAWINGS

FIGS. 1 to 10 are cross-sectional views showing a process of manufacturing an image sensor according to a first embodiment of the present invention.

FIGS. 11 to 20 are cross-sectional views showing a process of manufacturing an image sensor according to a second embodiment of the present invention.

### DETAILED DESCRIPTION

Embodiments of an image sensor and a method of manufacturing the same will be described with reference to the accompanying drawings.

When the terms “on” or “over” are used herein, when referring to layers, regions, patterns, or structures, it is understood that the layer, region, pattern or structure can be directly on another layer or structure, or intervening layers, regions, patterns, or structures may also be present. When the terms “under” or “below” are used herein, when referring to layers, regions, patterns, or structures, it is understood that the layer, region, pattern or structure can be directly under the other layer or structure, or intervening layers, regions, patterns, or structures may also be present.

FIG. 10 is a cross-sectional view showing an image sensor according to an embodiment.

Referring to FIG. 10, an image sensor according to an embodiment can comprise: a second conductive type diffusion layer 120 formed on a first conductive type substrate 100; a device isolating layer 140 formed in the second conductive type diffusion layer 120 to isolate the second conductive type diffusion layer 120 according to unit pixel; a gate 170 formed on the second conductive type diffusion layer 120; a first conductive type area 190 formed in a shallow area of the second conductive type diffusion layer 120 at one side of the gate 170; a first conductive type well area 200 formed in a deep area of the second conductive type diffusion layer 120 at the other side of the gate 170; and a floating diffusion area 210 formed in the first conductive type well area 200.

The first conductive type substrate 100 can be a high-concentration p-type substrate (p++), and can include a low-concentration p-type epitaxial layer (p-Epi) on the high-concentration p-type substrate.

A channel area 150 can be arranged on a surface of the second conductive type diffusion layer 120 below the gate 170. The channel area 150 can be arranged on the surface of the second conductive type diffusion layer 120 to isolate the second conductive type diffusion layer 120 from an interface surface of the substrate 100 and a gate insulating layer 160. Also, the channel area 150 can be arranged between the first conductive type area 190 and the first conductive type well area 200, making it possible to control threshold voltage. For example, the channel area 150 can be formed of p-type impurity at low concentration.

The gate insulating layer 160 can be arranged on the substrate 100. In an embodiment, the gate insulating layer 160 can be an oxide film.

According to an embodiment, the first conductive type substrate 100, the first conductive type area 190, and the first conductive type well region 200 can be formed of p-type impurity, and the second conductive type diffusion layer 120 and the floating diffusion region 210 can be formed of n-type impurity.

A barrier layer 130 of p-type impurity can be formed around the device isolating layer, making it possible to isolate the second conductive type diffusion layer 120 from the device isolating layer 140.

With the image sensor according to an embodiment, the n-type doping area of the photodiode is extended using the second conductive type diffusion layer 120, making it possible to improve the light sensitivity of the image sensor.

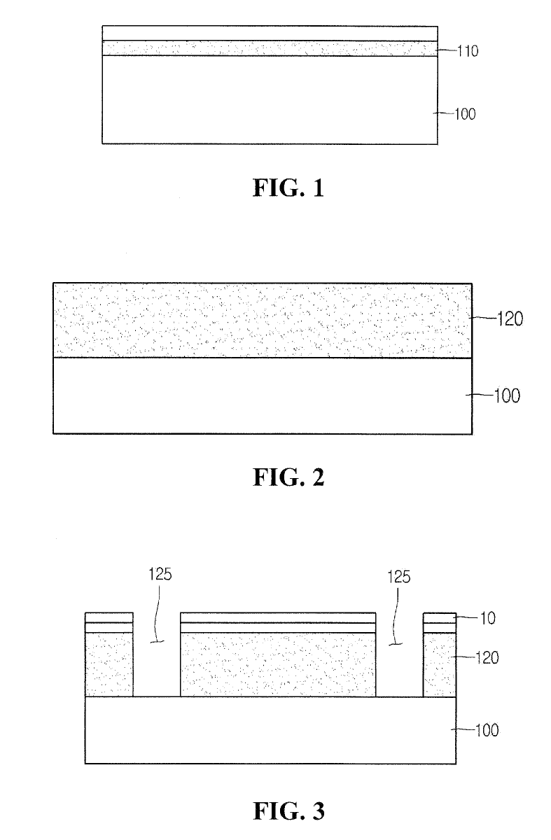

A process of manufacturing an image sensor will be described with reference to FIGS. 1 to 10.

Referring to FIG. 1, a second conductive type layer 110 can be formed in the first conductive type substrate 100.

The first conductive type substrate 100 can include a p-type substrate (p++), and a low-concentration p-type epitaxial layer (p-Epi) formed on the p++-type substrate.

The second conductive type layer 110 can be formed by implanting ions into the first conductive type substrate 100. The second conductive type layer 110 can be formed of n-type impurity, such as phosphorus (P) or arsenic (Ar). The second conductive type layer 110 can be formed to be spaced a distance from the surface of the first conductive type substrate 100.

Referring to FIG. 2, a second conductive type diffusion layer 120 can be formed on the first conductive type substrate 100. The second conductive type diffusion layer 120 can perform the role of an n-type doping area of the photodiode.

The second conductive type diffusion layer 120 can be formed by performing a thermal treatment process on the second conductive type layer 110. In a specific embodiment, the second conductive type diffusion layer 120 can be formed by performing an annealing process above about 5 to about 100 minutes at about 900° C. to about 1500° C. by a furnace. Then, the second conductive type layer 110 is diffused into the first conductive type substrate 100 above and below the second conductive type layer 110 to form the second conductive type diffusion layer 120.

The second conductive type diffusion layer 120 can be formed extending to the top surface of the first conductive type substrate 110 and down to a predetermined depth in the first conductive type substrate 100. For example, the depth of the second conductive type diffusion layer 120 can be between about 1.5 to 2.5 μm.

The second conductive type diffusion layer 120 can be formed of n-type impurity and the first conductive type substrate 100 can be formed of p-type impurity such that a lower junction area of the photodiode is formed on the first conductive type substrate 100. According to an embodiment, the second conductive type diffusion layer 120 can be formed up to a depth of 1.5 to 2.5 μm from the surface of the substrate 100.

By forming the n-type doping region (the second conductive type diffusion layer 120) on the first conductive type substrate 100 through a one-time ion implantation process without performing a mask process, it is possible to simplify the manufacturing process.

Referring to FIG. 3, in an embodiment, a trench 125 defining a prearranged area of a device isolating layer can be formed in the second conductive type diffusion layer 120. The trench 125 can be formed using a mask pattern 10 formed of a pad nitride film and a pad oxide film on the first conductive type substrate 100.

The mask pattern 10 can be used as an etching mask to selectively etch the second conductive type diffusion layer 120. The trench 125 can be formed by etching the second conductive type diffusion layer 120 until the first conductive type region of the substrate 100 is exposed. The trench 125 can be formed in the second conductive type diffusion layer 120. Therefore, the second conductive type diffusion layer 120 can be isolated by the trench 125 according to unit pixel.

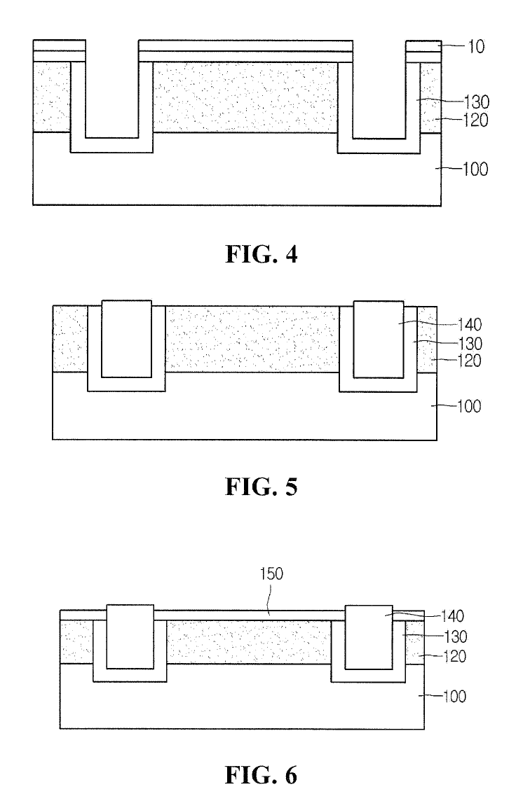

Referring to FIG. 4, a barrier layer 130 can be formed around the trench 125. The barrier layer 130 can be formed to enclose the trench 125 by ion-implanting p-type impurity. The barrier layer 130 can also use the mask pattern 10 as the ion implantation mask and may be formed by performing a tilt ion implantation of the p-type impurity. The barrier layer 130 can be formed to enclose the entire side wall and bottom surface of the trench 125. Therefore, the trench 125 and the second conductive type diffusion layer 120 can be isolated from each other by the barrier layer 130.

Referring to FIG. 5, a device isolating layer 140 can be formed in the trench 125. The device isolating layer 140 can be formed on the first conductive type substrate 100 and in the trench 125, defining the active area and the field area. The device isolating layer 140 can be formed by depositing an oxide film to gap-fill the trench 125 and then performing a chemical mechanical polishing (CMP) process. Then, the mask pattern 10 can be removed, and the second conductive type diffusion layer 120 formed on the first conductive type substrate 100 is isolated by the device isolating film 140.

In other words, the second conductive type diffusion layer 120 can be separated according to unit pixel by the device isolating layer 140. Therefore, each unit pixel is formed of the second conductive type diffusion layer 120 defined by the device isolating layer 140.

Referring to FIG. 6, a channel region 150 can be formed on the surface of the second conductive type diffusion layer 120. The channel area 150 controls the threshold voltage of the photo charge and may be formed by implanting the low-concentration p-type impurity (p0) to move charges. The channel area 150 can be formed over a shallow area of the second conductive type diffusion layer 120 so that the second conductive type diffusion layer 120 is not exposed at the surface of the substrate 100.

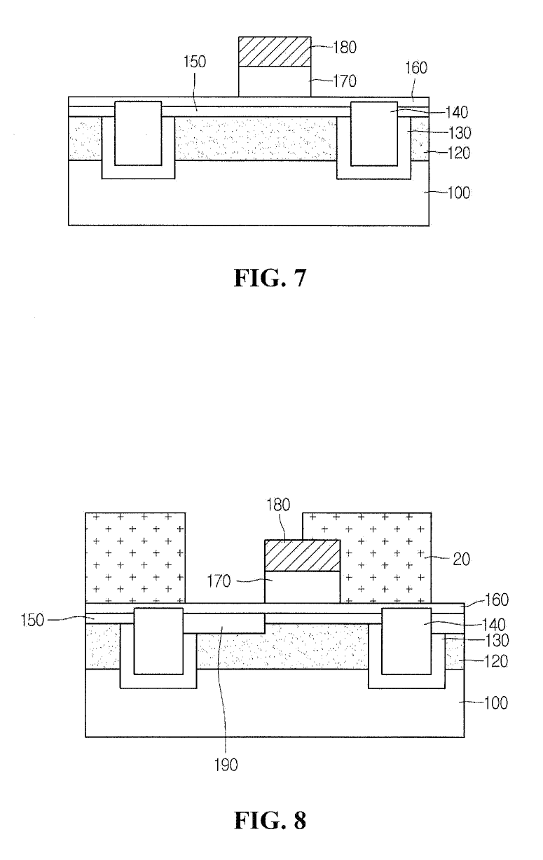

Referring to FIG. 7, a gate insulating layer 160 and gate electrodes including a transfer transistor gate 170 can be formed on the second conductive type diffusion layer 120 according to unit pixel.

The gate insulating layer 160 can be formed by depositing an oxide film on the first conductive type substrate 100.

To form the gate 170, a gate conductive layer and a cap insulator layer can be formed on the second conductive type diffusion layer 120. A cap pattern 180 can be formed by selectively etching the cap insulator layer by a photoresist pattern (not shown). Then, the gate 170 can be formed by etching the gate conductive layer using the cap pattern 180 as the etching mask. In an embodiment, the gate conductive layer can be formed in a single layer of polysilicon. In other embodiments, the gate conductive layer can include a plurality of layers. For example, the gate 170 can be formed of polysilicon, a metal such as tungsten, and metal silicide. The cap pattern 180 can be formed of an oxide film or a nitride film. In one embodiment, the cap pattern 180 can be formed to a thickness of about 2000 Å to about 5000 Å to protect the surface of the gate 170.

Although not shown, in certain embodiments, the gate insulating layer 160 can also be etched.

Referring to FIG. 8, a first conductive type area 190 can be formed on the surface of the second conductive type diffusion layer 120 at one side of the gate 170. The first conductive type area 190 can further isolate the second conductive type diffusion layer 120 from the top surface of the substrate 100.

The first conductive type area 190 can be formed by forming a first photoresist pattern 20 on the first conductive type substrate 100 to expose the one side of the gate 170. Then, high-concentration p-type impurity (p++) can be implanted using the first photoresist pattern 20 as the ion implantation mask. The cap pattern 180 on the upper surface of the gate 170 can remain to protect the gate 170 when forming the first conductive type area 190.

The upper and lower portions of the second conductive type diffusion layer 120 are isolated by the first conductive type substrate 100 and the first conductive type area 190. Also, side boundaries of the second conductive type diffusion layer 120 can be isolated by the barrier layer 130 and the device isolating layer 140.

As described above, the photodiode can have a PNP structure by the first conductive type substrate 100, the second conductive type diffusion layer 120, and the first conductive type area 190. Also, because the second conductive type diffusion layer 120 is formed in the overall area between the device isolating layers 140, it is possible to extend the depletion area.

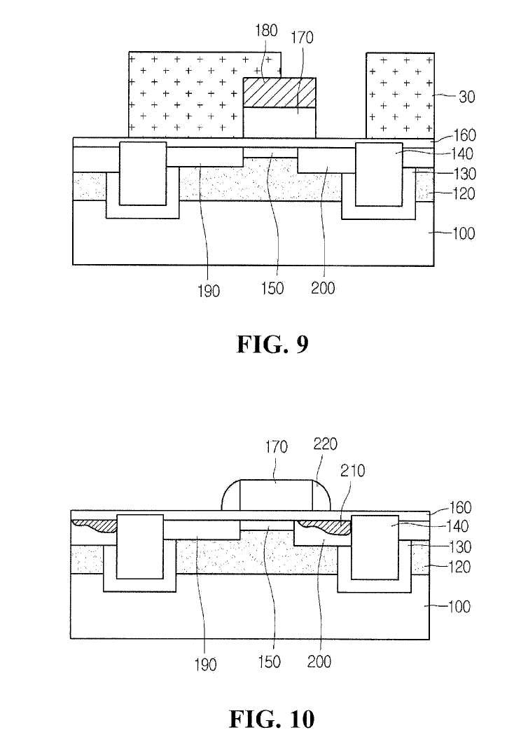

Referring to FIG. 9, a first conductive type well area 200 can be formed in the second conductive type diffusion layer 120 at the other side of the gate 170. The first conductive type well area 200 can be formed by forming a second photoresist pattern 30 on the first conductive type substrate 100 to expose the other side of the gate 170. Then, p-type impurity can be implanted using the second photoresist pattern 30 as the ion implantation mask. For example, the first conductive type well area 200 can be formed by performing a tilt ion implantation of the p-type impurity, such as boron at high energy. In particular, ion-implanting the p-type impurity can be performed at an energy and tilt so as to not overwhelmingly transmit ions into the cap pattern 180 and the gate 170. Then, the second photoresist pattern 30 can be removed. Accordingly, the first conductive type well area 200 can be formed in the second conductive type diffusion layer 120 overlapped with the channel area 150.

In other words, the first conductive type well area 200 can be formed in the second conductive type diffusion layer 120 overlapped with the portion of the channel area implant at the side of the gate 170, making it possible to further isolate the second conductive type diffusion layer 120 from the top surface of the substrate 100.

Referring to FIG. 10, a floating diffusion area 210 can be formed in the first conductive type well area 200.

An LDD area can be formed as part of the floating diffusion area 210 and aligned to the gate 170. The LDD area can be formed by performing an ion implantation process using a photoresist pattern (not shown) exposing the first conductive type well 200 at the side of the gate 170 as the ion implantation mask. The LDD area can be formed of n-type impurity at low concentration.

Then, an insulating layer can be deposited over the substrate 100 including the gate 170, and a spacer 220 can be formed on the side walls of the gate 170 by performing an etching process with respect to the insulating layer.

The floating diffusion area 210 can be formed to be aligned to the spacer 220 by performing an ion implantation process using a photoresist pattern (not shown) exposing the first conductive type well 200 at the side of the gate 170 and the spacer 220 as the ion implantation mask. The floating diffusion area 210 can be formed of n-type impurity at high concentration.

Since the floating diffusion area 210 is formed in the first conductive type well area 200, the floating diffusion area 210 can be isolated from the second conductive type diffusion layer 120.

With the method of manufacturing the image sensor according to an embodiment, the second conductive type diffusion layer, which provides the n-type doping area of the photodiode, is formed on an upper region of a conductive substrate by a one-time ion plantation process so that the mask process is omitted, making it possible to simplify the manufacturing process.

Also, by forming the second conductive type diffusion layer on an entire region of the first conductive type substrate by the ion implantation process, the second conductive type diffusion layer is extended to boundaries of a unit pixel, making it possible to suppress a reduction of the light sensitivity and stably control the charge transfer characteristics between the gate and the photodiode.

Also, according to embodiments, the floating diffusion area is formed in the second conductive type diffusion layer, making it possible to extend the capacity of the photodiode.

Also, the second conductive type layer is isolated from the gate by the channel area below the gate, making it possible to improve the charge transfer characteristic. In other words, when the channel area and the photodiode are aligned at the existing gate edge to be connected to each other, the electron transfer characteristic is largely affected by the fringing field of the gate edge so that it may not be stable. Accordingly, the first conductive type diffusion layer can be formed extending below the channel area to directly determine the transfer characteristics by the channel voltage and the gate voltage, making it possible to stably control the electron transfer characteristics.

FIGS. 11 to 20 show a method of manufacturing an image sensor according to a second embodiment.

Referring to FIG. 11, a second conductive type layer 310 can be formed in the first conductive type substrate 300.

The first conductive type substrate 300 can include a p-type substrate (p++) and a low-concentration p-type epitaxial layer (p-Epi) formed on the p++ substrate.

The second conductive type layer 310 can be formed in the first conductive type substrate 300 by an ion implantation process. The second conductive type layer 310 can be formed, for example, by ion-implanting n-type impurity.

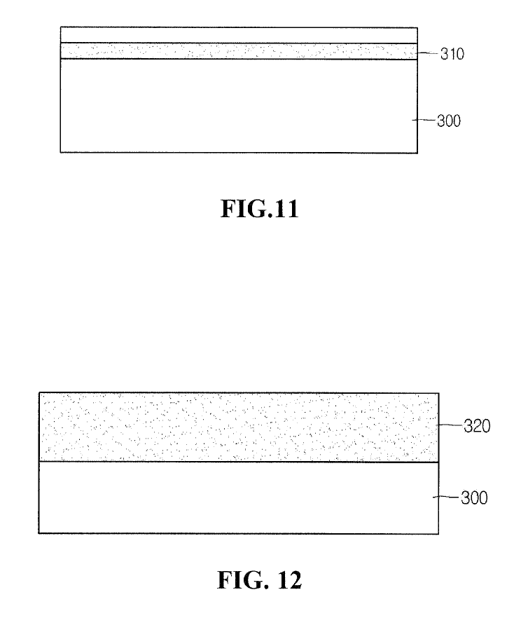

Referring to FIG. 12, a second conductive type diffusion layer 320 can be formed on the first conductive type substrate 300 by using the second conductive type layer 310. The second conductive type diffusion layer 320 can perform the role of an n-type doping area of a photodiode.

The second conductive type diffusion layer 320 can be formed by performing a thermal treatment process on the second conductive type layer 310. In a specific embodiment, the second conductive type diffusion layer 320 can be formed by performing an annealing process above 5 to 600 minutes at 900 to 1500° C. by a furnace. Then, the second conductive type layer 310 is diffused into the first conductive type substrate 300 above and below the second conductive type layer 310 to form the second conductive type diffusion layer 320. For example, the second conductive type diffusion layer 320 can be provided to a depth of about 1.5 to about 2.5 μm.

Since the second conductive type diffusion layer 320 can be formed of n-type impurity and the first conductive type substrate 300 can be formed of p-type impurity, a lower junction area of the photodiode can be provided on the first conductive type substrate 300. By forming the second conductive type diffusion layer 320 in the first conductive type substrate 100 by a one-time ion implantation process without performing the mask process, it is possible to simplify the manufacturing process.

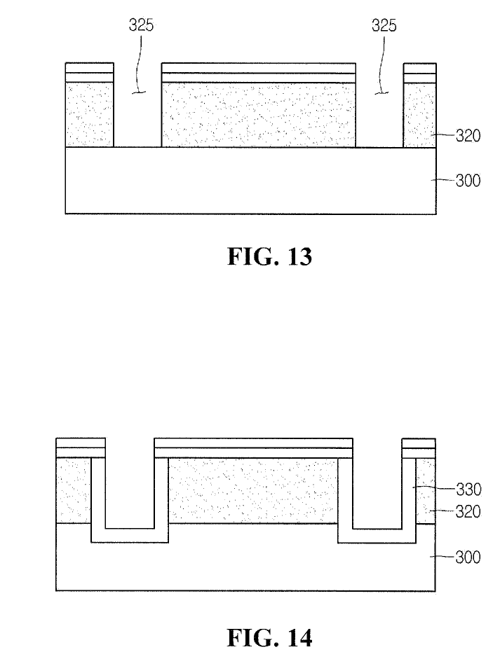

Referring to FIG. 13, a trench 325 defining a prearranged area of a device isolating layer can be formed in the second conductive type diffusion layer 320. To form the trench 325, a mask pattern 50 formed of a pad nitride film and a pad oxide film can be formed on the first conductive type substrate 300. The mask pattern 50 can be used as an etching mask to selectively etch the second conductive type diffusion layer 320. The trench 325 can be formed by etching the second conductive type diffusion layer 320 until the first conductive type region of the substrate 300 is exposed. Accordingly, the trench 325 can be formed in the second conductive type diffusion layer 320. Therefore, the second conductive type diffusion layer 320 can be isolated according to unit pixel by the trench 325.

Referring to FIG. 14, a barrier layer 330 can be formed around the trench 325. The barrier layer 330 can be formed to enclose the trench 325 by ion-implanting p-type impurity. The barrier layer 330 can also use the mask pattern 50 as the ion implantation mask and may be formed by performing a tilt ion implantation of the p-type impurity. The barrier layer 330 can be formed to enclose the entire side wall and bottom surface of the trench 325. Therefore, the trench 325 and the second conductive type diffusion layer 320 can be isolated from each other by the barrier layer 330.

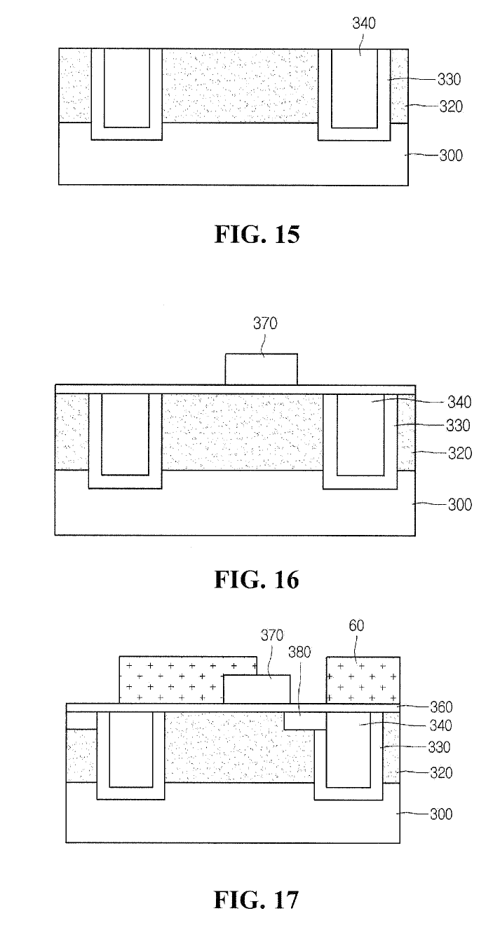

Referring to FIG. 15, a device isolating layer 340 can be formed in the trench 325. The device isolating layer 340 can be formed on the first conductive type substrate 300 and in the trench 125, making it possible to define the active area and the field area. The device isolating layer 340 can be formed by depositing an oxide film to gap-fill the trench 325 and then performing a CMP process. Then, the mask pattern 50 is removed, and the second conductive type diffusion layer 320 formed on the first conductive type substrate 300 is isolated by the device isolating film 340. In other words, the second conductive type diffusion layer 320 can be isolated by the device isolating layer 340 for each unit pixel. Therefore, the unit pixels defined between the device isolating layer 340 can be formed of the second conductive type diffusion layer 320.

Referring to FIG. 16, a gate insulating layer 360 and a gate 370 of a transfer transistor can be formed on the second conductive type diffusion layer 320.

The gate insulating layer 360 can be formed by depositing an oxide film on the first conductive type substrate 300.

The gate 370 can be formed by depositing a gate conductive layer on the gate insulating layer 360. Then, a photolithography and etching process can be performed to provide the gate 370. In one embodiment, the gate 370 can be formed of polysilicon. In another embodiment, the gate 370 can be formed of plural layers of, for example, polysilicon, a metal such as tungsten, and metal silicide.

Referring to FIG. 17, a first conductive type layer 380 can be formed in the second conductive type diffusion layer 320 at a side of the gate 370. The first conductive type layer 380 can further isolate the second conductive type diffusion layer 320. In one embodiment to form the first conductive type layer 380, a first photoresist pattern 60 can be formed on the first conductive type substrate 300 to expose the second conductive type diffusion layer 320 at the side of the gate 370. The first conductive type layer 380 can be formed by ion-implanting p-type impurity at high concentration using the first photoresist pattern 60 as an ion implantation mask.

Therefore, the first conductive type layer 380 can be aligned at the side of the gate 370, making it possible to isolate the second conductive type diffusion layer 320 from the surface of the first conductive type substrate 300.

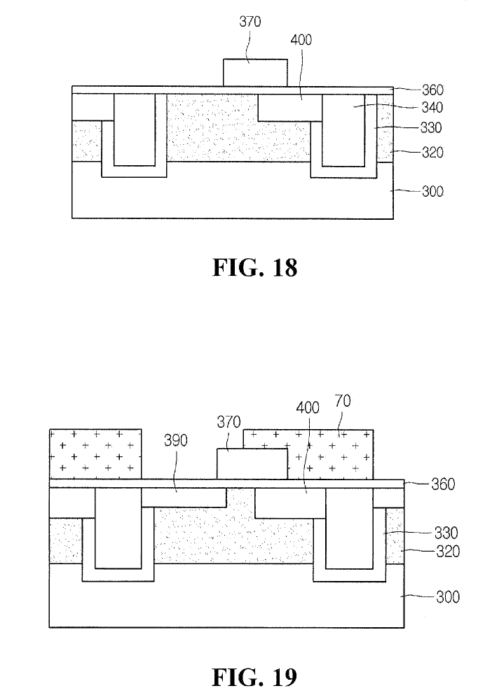

Referring to FIG. 18, a first conductive type well area 400 can be formed at the side of the gate 370 by performing an annealing process on the first conductive type layer 380. Then, the impurity implanted in the first conductive type layer 380 is diffused to form the first conductive type well region 400. Therefore, the first conductive type well region 400 can be extended to a deep area of the first conductive type substrate 300 and below a portion of the gate 370. The extension of the first conductive type well can further support isolation of the second conductive type diffusion layer 320.

Also, the first conductive type well area 400 can be formed to be overlapped with the gate 370 in a predetermined area, making it possible to allow the first conductive type well area 400 to control the threshold voltage of the transfer transistor.

Referring to FIG. 19, a first conductive type area 390 can be formed in the second conductive type diffusion layer 320 at a side of the gate 370 opposite the first conductive type well area 400. The first conductive type area 390 can further isolate the second conductive type diffusion layer from the surface of the first conductive type substrate 300. The first conductive type area 390 can be formed by forming a second photoresist pattern 70 on the first conductive type substrate 300 to expose the one side of the gate 370. Then, p-type impurity can be implanted at high concentration using the photoresist pattern 70 as the ion implantation mask. Further, an annealing process can be performed on the first conductive type area 390.

As described above, a photodiode having a PNP structure is formed by the first conductive type substrate 300, the second conductive type diffusion layer 320, and the first conductive type area 390. At this time, the second conductive type diffusion layer 320 is formed over the area between the device isolating layer 340, making it possible to extend the depletion area.

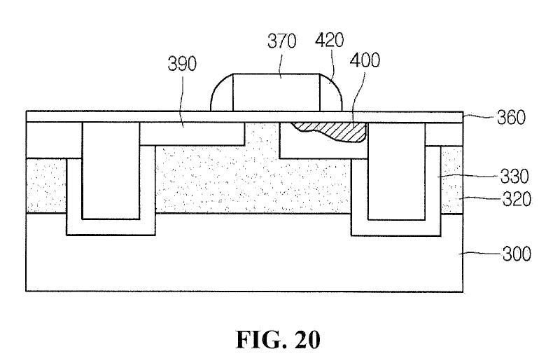

Referring to FIG. 20, a floating diffusion area 410 can be formed in the first conductive type well area 400. The floating diffusion area 410 can include an LDD area aligned to the gate 370 and formed by an ion implantation process using a photoresist pattern (not shown) exposing the first conductive type well 400 at the side of the gate 370 as an ion implantation mask. The LDD area can be formed of low-concentration n-type impurity.

Next, an insulating layer can be deposited over the first conductive type substrate 300 including the gate 370, and etched to form a spacer 420 on the side walls of the gate 370.

The floating diffusion area 410 can be formed in the first conductive type well area 400 aligned to the spacer 420 by performing an ion implantation process using a photoresist pattern (not shown) exposing the first conductive type well 400 at the side of the gate 370 and the spacer 420 as the ion implantation mask. The floating diffusion area 410 can be formed of high-concentration n-type impurity.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An image sensor comprising:
a second conductive type diffusion layer on a first conductive type substrate;
a device isolating layer in the second conductive type diffusion layer, isolating the second conductive type diffusion layer according to unit pixel;
a gate disposed on the second conductive type diffusion layer;
a first conductive type area on the second conductive type diffusion layer at one side of the gate;
a first conductive type well area on the second conductive type diffusion layer at the other side of the gate; and
a floating diffusion area in the first conductive type well area.

2. The image sensor according to claim 1, further comprising a first conductive type channel area below the gate and between the first conductive type area and the floating diffusion area.

3. The image sensor according to claim 1, further comprising a gate insulating layer arranged on the first conductive type substrate including the second conductive type diffusion layer and below the gate.

4. The image sensor according to claim 1, wherein the first conductive type substrate, the first conductive type area, and the first conductive type well area are p-type and wherein the second conductive type diffusion layer and the floating diffusion area are n-type.

5. The image sensor according to claim 1, further comprising a first conductive type barrier layer disposed around the device isolating layer.

6. The image sensor according to claim 1, wherein the first conductive type well area extends below a portion of the gate.

7. A method of manufacturing an image sensor, comprising:
forming a second conductive type diffusion layer on a first conductive type substrate;
forming a device isolating layer in the second conductive type diffusion layer to isolate the second conductive type diffusion layer according to unit pixel;
forming a gate on the second conductive type diffusion layer;
forming a first conductive type area in the second conductive type diffusion at one side of the gate;
forming a first conductive type well area in the second conductive type diffusion layer at the other side of the gate; and
forming a floating diffusion area in the first conductive type well area.

8. The method according to claim 7, wherein forming the second conductive type diffusion layer comprises:
forming a second conductive type layer by ion-implanting n-type impurity into the first conductive type substrate; and
performing a thermal treatment process to diffuse the n-type impurity up to an upper area of the first conductive type substrate.

9. The method according to claim 7, wherein forming the device isolating layer comprises:
forming a trench in the second conductive type diffusion layer exposing a region of the first conductive type substrate;
forming a barrier layer to surround the trench by ion-implanting p-type impurity in the trench; and
filling an oxide layer in the trench.

10. The method according to claim 7, further comprising forming a channel area by ion-implanting p-type impurity on the surface of the second conductive type diffusion layer.

11. The method according to claim 7, further comprising forming a gate insulating layer on the first conductive type substrate including the second conductive type diffusion layer.

12. The method according to claim 7, wherein forming the first conductive type well area comprises:
forming a photoresist pattern on the first conductive type substrate to expose the second conductive type diffusion layer at the other side of the gate; and
ion-implanting p-type impurity deeply into the second conductive type diffusion layer by a tilt ion implantation process using the photoresist pattern as an ion implantation mask.

13. The method according to claim 12, further comprising forming a cap pattern on the gate, wherein the cap pattern protects the gate during forming the first conductive type well area.

14. The method according to claim 7, wherein forming the first conductive type well area comprises:
forming a photoresist pattern on the first conductive type substrate to expose the second conductive type diffusion layer at the other side of the gate;
forming a first conductive type layer by ion-implanting p-type impurity at high concentration into the second conductive type diffusion layer by an ion implantation process using the photoresist pattern as the ion implantation mask; and
performing a thermal process to diffuse the p-type impurity.

15. The method according to claim 7, wherein forming the gate comprises:
forming a gate conductive layer on the second conductive type diffusion layer;
forming a cap pattern on the gate conductive layer; and
etching the gate conductive layer using the cap pattern as an etching mask.

16. The method according to claim 15, wherein forming the first conductive type well area comprises:
forming a photoresist pattern on the first conductive type substrate to expose the second conductive type diffusion layer at the other side of the gate; and
ion-implanting p-type impurity deeply into the second conductive type diffusion layer by a tilt ion implantation process using the photoresist pattern as an ion implantation mask, wherein the cap pattern protects the gate during the ion-implanting of the p-type impurity.
